(19) United States
(12) Patent Application Publication
(10) Pub. No.: US 2009/0279272 A1
(43) Pub. Date: Nov. 12, 2009

(54) SOLDERING PAD AND CIRCUIT BOARD UTILIZING THE SAME

(75) Inventor: Li-Chien Sun, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/206,732

(22) Filed: Sep. 8, 2008

(30) Foreign Application Priority Data
May 8, 2008 (CN) 200810301473.X

(51) Int. Cl. H05K 7/06

(52) U.S. Cl. 361/767

(57) ABSTRACT

An exemplary soldering pad includes two opposite sides and defining interleaved cutouts at the opposite sides. Outer extremities of the soldering pad at the cutouts are in closer proximity to a lead soldered to the soldering pad than that at other parts. During soldering, soldering tin near the cutouts can significantly prevent shrinkage toward other parts of the soldering pad.

### BACKGROUND

1. Field of the Invention

The present invention relates to solder pads and, particularly, to a solder pad that can reduce voiding problems and a circuit board utilizing the pad.

2. Description of Related Art

In surface mount technology (SMT), a rectangular lead from electronic devices is generally soldered to a soldering pad with a rectangular configuration. However, molten tin, applied between the lead and the soldering pad, teds to inherently exert surface tension force on the surface thereof. The surface tension is inclined to shrink the molten tin inwardly to be configured with the lowest surface. As a result, voiding problems are likely between the rectangular lead and the soldering pad.

What is needed, therefore, is a solder pad that can reduce voiding problems.

### SUMMARY

An exemplary soldering pad includes two opposite sides and defining interleaved cutouts thereat. Outer extremities of the soldering pad at the cutouts are in closer proximity to a lead soldered to the soldering pad than that at other parts. During soldering, soldering tin near the cutouts can significantly prevent shrinkage toward other parts of the soldering pad.

Other advantages and novel features of the present invention will become more apparent from the following detailed description of an embodiment/embodiments when taken in conjunction with the accompanying drawings, in which:

### BRIEF DESCRIPTION OF THE DRAWINGS

FIG. 1 is a plan view of a soldering pad in accordance with a first embodiment, set on a circuit board.

FIG. 2 is similar to FIG. 1, but with lead soldered to the soldering pad.

FIG. 3 is a plan view of a soldering pad in accordance with a second embodiment, set on a circuit board with lead soldered thereto.

### DETAILED DESCRIPTION

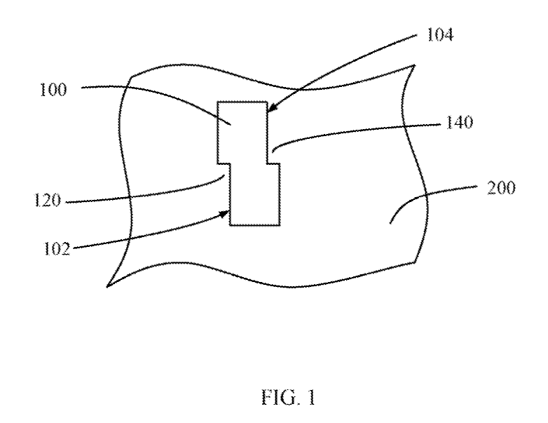

Referring to FIG. 1, a soldering pad 100 in accordance with a first embodiment of the present invention is deployed on a circuit board 200. The soldering pad 100 comprises two opposite sides 102, 104, and defines two rectangular cutouts 120, 140 interleaved at the opposite sides 102, 104, respectively. The soldering pad 100 is copper foil. In the embodiment, the cutouts 120, 140 are diagonally located at corners of the soldering pad 100. The length of each cutout 120/140 is half the length of and parallel to the corresponding side 102/104. Moreover, the total length of the cutouts 120, 140 is equal to the length of each side 102/104.

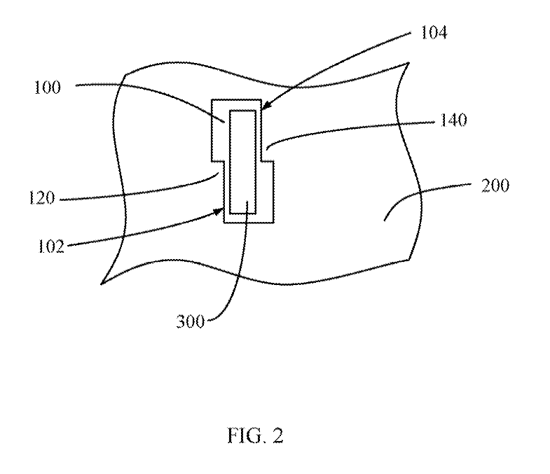

Referring to FIG. 2, the soldering pad 100 is provided with a rectangular lead 300 soldered thereto. The soldering pad 100 has an area larger than that of the lead 300. Outer extremities of the soldering pad 100 at the cutouts 120, 140 are in closer proximity to the lead 300 soldered to the soldering pad 100 than at other parts. During soldering, soldering tin (not shown) near the cutouts 120, 140 can significantly prevent shrinkage toward other parts of the soldering pad 100, with voiding problems effectively avoided.

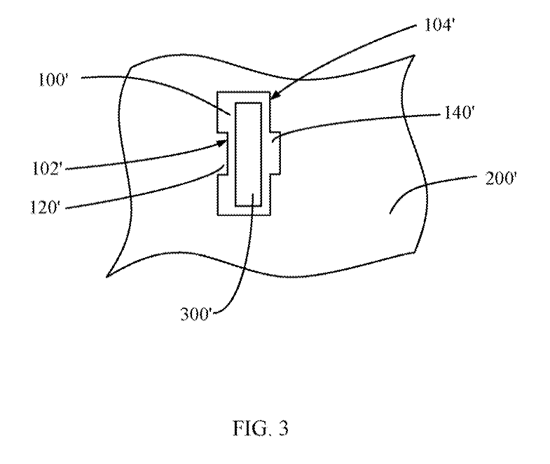

Referring to FIG. 3, a soldering pad 100′ in accordance with a second embodiment of the present invention is set on a circuit board 200′ with a lead 300′ soldered thereto. The soldering pad 100′ comprises two opposite sides 102′, 104′, and defines a cutout 120′ at the side 102′ and two cutouts 140′ at the side 104′. The cutouts 120′, 140′ are interleaved at the side 102′, 104′. Outer extremities of the soldering pad 100′ at the cutouts 120′, 140′ are in closer proximity to the lead 300′ soldered to the soldering pad 100′ than that at other parts. During soldering, soldering tin (not shown) near the cutouts 120′, 140′ can significantly prevent shrinkage toward other parts of the soldering pad 100′.

In the second embodiment, the cutout 120′ is located at a central portion of the side 102′. The cutouts 140′ are separately placed at opposite ends of the side 104′. A length of each cutout 120′/140′ is one-third the length of and parallel to the corresponding side 102′/104′, respectively. In summary, the total length of the cutouts 120′ 140′ is equal to the length of each side 102′/104′.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A soldering pad comprising two opposite sides and defining interleaved cutouts at the opposite sides.

2. The soldering pad as claimed in claim 1, wherein the soldering pad is rectangular, and the cutouts are diagonally located at a pair of corners of the soldering pad.

3. The soldering pad as claimed in claim 1, wherein a total length of the cutouts is equal to a length of each of the sides.

4. The soldering pad as claimed in claim 3, wherein the cutouts are the same length and parallel to each of the sides.

5. The soldering pad as claimed in claim 1, wherein the cutouts are the same length and parallel to each of the sides.

6. The soldering pad as claimed in claim 1, wherein two of the cutouts are disposed at opposite ends of one of the sides.

7. The soldering pad as claimed in claim 1, wherein the cutouts are rectangular.

8. A circuit board comprising a soldering pad, wherein the soldering pad comprises two opposite sides and defines interleaved cutouts at the opposite sides.

9. The circuit board as claimed in claim 8, wherein the soldering pad is rectangular, and wherein the cutouts are located at a pair of diagonal corners of the soldering pad.

10. The soldering pad as claimed in claim 8, wherein a total length of the cutouts is equal to a length of one of the sides.

11. The soldering pad as claimed in claim 10, wherein the cutouts are the same length and parallel to each of the sides.

12. The soldering pad as claimed in claim 8, wherein the cutouts are the same length and parallel to each of the sides.

13. The soldering pad as claimed in claim 8, wherein two of the cutouts are placed at opposite ends of one of the sides.

14. The soldering pad as claimed in claim 8, wherein the cutouts are rectangular.

15. A circuit board comprising a rectangular soldering pad with two cutouts diagonally defined at a pair of corners thereof.

16. The circuit board as claimed in claim 15, wherein the cutouts are rectangular.

17. The circuit board as claimed in claim 16, wherein a length of each of the cutouts is half the length of the soldering pad.
